(19) United States
(12) Patent Application Publication
(10) Pub. No.: US 2003/0183245 A1
(43) Pub. Date: Oct. 2, 2003

(54) Surface silanization

(76) Inventor: Min-Shyan Sheu, Chelmsford, MA (US)

Correspondence Address: FISH & RICHARDSON PC, 225 FRANKLIN ST, BOSTON, MA, 02110, US

(21) Appl. No.: 10/113,076

(22) Filed: Apr. 1, 2002

(51) Int. Cl. C23C 16/00; B08B 6/00

(52) U.S. Cl. 134/1.2; 427/535; 427/255.28; 134/1.1; 156/345.43; 156/345.47; 156/345.48

(57) ABSTRACT

A substrate surface is plasma cleaned and silanized in a chamber. Plasma is generated in the chamber to clean the substrate surface. Gas containing an organosilane compound is introduced into the same chamber to silanized the cleaned surface. Water is deposited on the substrate surface to facilitate silane coupling reaction. A layer of covalently bonded silane molecules having functional groups is thus produced on the substrate surface. The substrate is then cured by a baking process.

### BACKGROUND

Many analytical and preparative methods used in biology and medicine are based on attachment of compounds, such as peptide ligands or oligonucleotide probes, to a substrate. Frequently, multiple compounds are attached, each at a predefined location, onto the surface of the substrate. Such attachment can be achieved in a number of different ways, including covalent and non-covalent bonding.

A number of protocols have been developed to covalently attach a compound to a substrate, such as a microscopic glass slide. In one example, an oligonucleotide is synthesized directly on the substrate surface using a photolithographic process. In another example, a nucleic acid, such as a cloned cDNA, a PCR product, or a synthetic oligonucleotide, is deposited onto the substrate in the form of an array. The array can then be used in hybridization assays in order to determine the presence or abundance of particular sequences in a sample.

Before the compounds can be attached to a substrate, the substrate surface must be thoroughly cleaned to remove contaminants, typically by a chemical wash process. Then, the substrate surface is modified with silane having a functional group (e.g., aldehydes and amines) to facilitate attachment of the compounds. This can be achieved by a vapor deposition process or a solution coating process.

### SUMMARY

In one aspect, the invention is directed towards a method of treating a substrate surface by providing a chamber having a substrate, cleaning a surface of the substrate in the chamber with a plasma, and silanizing the cleaned surface in the chamber to produce a layer of covalently bonded silane molecules having functional groups.

Implementations of the invention may include one or more of the following features. Each of the functional groups is amine, aldehyde, epoxy, isocyanide, thiol, mercapto, hydroxyl, carboxyl, vinyl, halocarbon, disulfide, halogen-substituted alkyl, succinimide, methacryl or acryl. The plasma is O₂ plasma, air plasma, CO₂ plasma, Ar plasma, N₂ plasma, hydrogen plasma, helium plasma, water plasma, hydrogen peroxide plasma, or a combination thereof. Water or hydrogen peroxide is deposited on the surface of the substrate, either before, during, or after the silanizing step. The silanized substrate is cured by a baking process. The silanizing step is performed without cleaning the chamber. The portion of the substrate at the surface is composed of glass, quartz, ceramic, silicon, metal, gallium arsenide, or polymer.

In another aspect, the invention is directed towards a method of treating a substrate surface by providing a substrate in a chamber, providing water vapor in the chamber, and generating a plasma from the water vapor to clean a surface of the substrate.

Implementations of the invention may include one or more of the following features. The cleaned surface is silanized to produce a silane layer having covalently bonded silane molecules. The plasma generating step is performed at 20 to 300° C. and at a chamber pressure of 50 to 1000 mTorr.

In another aspect, the invention is directed towards a method of treating a substrate surface by providing a substrate in a chamber, providing hydrogen peroxide vapor in the chamber, generating a plasma from the hydrogen peroxide vapor to clean a surface of the substrate, and providing an organosilane gas in the chamber to silanize the cleaned surface.

In another aspect, the invention is directed towards a method of treating a substrate surface by providing a chamber, placing a substrate into the chamber, generating a plasma in the chamber, and introducing a first gas having first organosilane molecules into the chamber.

Implementations of the invention may include one or more of the following features. A second gas having second organosilane molecules is introduced into the chamber. Water vapor or hydrogen peroxide vapor is introduced into the chamber, either before, during, or after the second gas is introduced into the chamber.

In another aspect, the invention is directed towards an apparatus having a chamber, electrodes to supply power to the chamber for generating a plasma, an inlet to allow a gas suitable for generating the plasma to enter the chamber, and a vessel coupled to the chamber for containing an organosilane solution.

Implementations of the invention may include one or more of the following features. The organosilane solution has a compound suitable for silanizing a surface of a substrate placed in the chamber. A power supply is coupled to the electrodes to supply power to the chamber to generate the plasma in the chamber. A heater is used to heat the solution. A second vessel also coupled to the chamber is used to store water or hydrogen peroxide.

In another aspect, the invention is directed towards an apparatus having a chamber, means for plasma cleaning a surface of a substrate in the chamber, and means for silanizing the cleaned surface in the chamber.

Implementations of the invention may include one or more of the following features. The apparatus includes means for depositing water or hydrogen peroxide on the surface of the substrate. A first vessel coupled to the chamber stores a first organosilane solution. A second vessel also coupled to the chamber stores a second organosilane solution. The silanizing means includes additional vessels storing organosilane solutions. The first, the second, and the additional vessels each stores a different organosilane solution. A computer selects organosilane solutions for silanizing the cleaned surface according to a predefined protocol that defines the sequence or combination of the selected organosilane solutions for silanizing the cleaned surface.

In another aspect, the invention is directed towards an apparatus having a first chamber, a second chamber, and a gate disposed between the first and the second chambers. The gate is movable between a first position where the first chamber is connected to the second chamber and a second position where the first chamber is closed off from the second chamber. The apparatus includes electrodes to supply power suitable for generating a plasma to the first chamber, an inlet to allow a gas to enter the first chamber, the first gas suitable for generating the plasma to clean a substrate in the first chamber. A vessel coupled to the second chamber contains an organosilane solution having a compound suitable for silanizing a surface of the substrate.

Implementations of the invention may include one or more of the following features. A heater is used to heat the organosilane solution. A second vessel also coupled to the second chamber stores water. The apparatus includes means for moving a substrate from the first support to the second support when the gate is moved to the first position. The apparatus includes additional vessels also coupled to the second chamber, the additional vessels storing organosilane solutions, the first vessel and the additional vessels each storing a different organosilane solution. A computer is used to select water (or hydrogen peroxide) and/or organosilane solutions from the first, the second, and the additional vessels for silanizing the substrate surface, the selection of water and/or solutions performed according to a predefined protocol. The predefined protocol defines the sequence or combination of the selected organosilane solutions.

In another aspect, the invention is directed towards an apparatus having a chamber, electrodes to supply power to the chamber for generating a plasma, an inlet coupled to the chamber to allow a gas suitable for generating a plasma to enter the chamber, an inlet coupled to the chamber to allow another gas to enter the chamber, the other gas including an organosilane compound, and an outlet coupled to the chamber to allow the gases to exit the chamber.

Implementations of the invention may include one or more of the following features. The apparatus includes a heater that receives a vessel, the vessel containing an organosilane solution that generates an organosilane gas when the solution is heated by the heater. A power supply is coupled to the electrodes to supply power for generating the plasma. A mass flow controller is coupled to the first inlet to regulate the gas flowing through the first inlet. A computer controls the power supply, the mass flow controller, and the heater.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIGS. 1-4 show silanization systems.

Like reference symbols in the various drawings indicate like elements.

### DETAILED DESCRIPTION

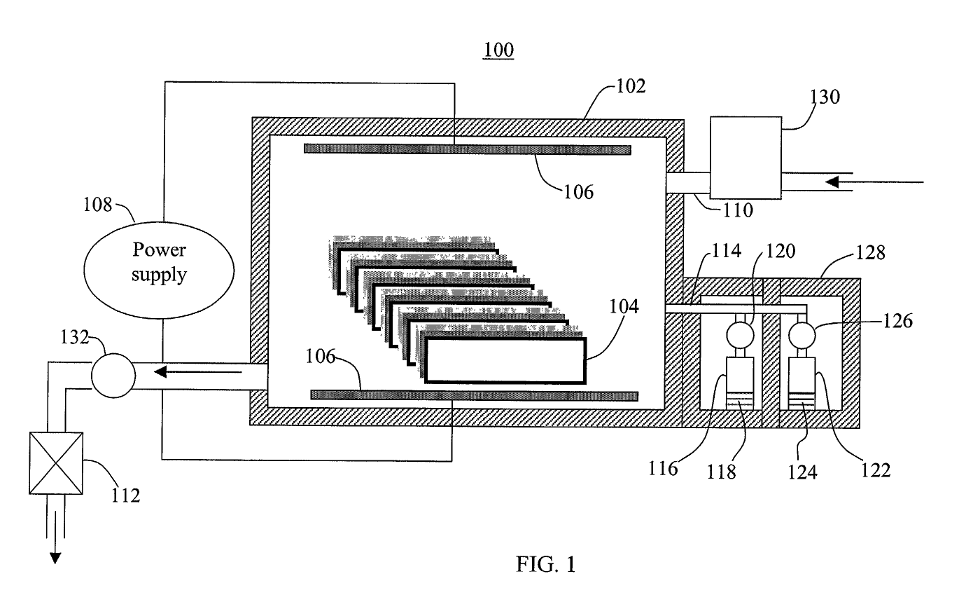

A compact silanization system is provided by using a single chamber for both cleaning and silanization of substrates, such as glass slides. Referring to FIG. 1, a silanization system 100 includes a chamber 102 that accommodates a set of glass slides 104. Electrodes 106 are provided in chamber 102 and are connected to a plasma power supply 108. A gas for generating a plasma is introduced into chamber 102 through inlet 110 and regulated by a mass flow controller 130. The gas is energized into plasma by power supplied through electrodes 106. The plasma reacts with the set of glass slides 104 and removes contaminants on the surface of the slides. A vacuum pump 112 removes the contaminants and gases from chamber 102. An inlet 114 is used to introduce organosilane vapor into chamber 102. A vessel 116 that contains an organosilane solution 118 is connected to inlet 114 through a valve 120. Vessel 116 is placed in an oven 128 that heats the solution 118 to produce organosilane vapor. A silane coupling reaction occurs when the organosilane vapor enters chamber 102 and reacts with glass slides 104. After a preset amount of time, a layer of organosilane is deposited on the surface of the glass slides. The silanized glass surface allows attachment of target compounds, e.g., cDNA, PCR products, oligos, and proteins in array assay.

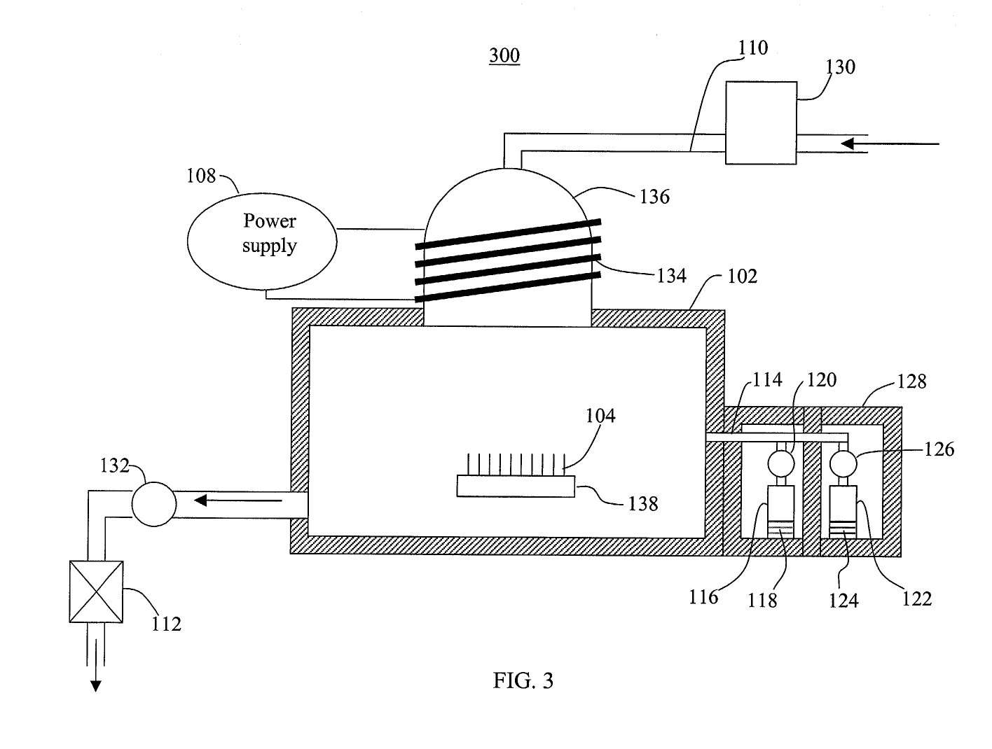

The following is a description of a cleaning process using the silanization system 100. Initially, glass slides 104 are mounted on a slide holder 138 (see FIG. 3) and placed inside chamber 102. The chamber is maintained at a temperature between room temperature (e.g., 20° C.) to 300° C., preferably between room temperature to 100° C. Mass flow controller 130 and valve 120 are initially adjusted so that no gas is introduced into chamber 102. A valve 132 placed between chamber 102 and vacuum pump 112 is opened to allow the vacuum pump to pump air out of the chamber. When the pressure inside chamber 102 lowers to a baseline pressure, valve 132 is closed. The baseline pressure can be 0 to 500 mTorr, preferably 10 to 100 mTorr. Mass flow controller 130 is turned on to allow a plasma gas to enter chamber 102. Hereafter, “plasma gas” refers to the gas that is ionized to generate a plasma. Examples of suitable plasma gases are O₂, CO_{2, Ar, N}₂, water vapor, hydrogen peroxide vapor, and room air. A mixture of the above gases may be used as the plasma gas. Hydrogen plasma and helium plasma may be used. Other types of gas or gas mixture suitable for plasma cleaning may also be used.

As the plasma gas enters chamber 102, the pressure inside the chamber increases. Mass flow controller 130 is adjusted to maintain a constant flow of plasma gas into the chamber when a preset pressure is reached. The preset pressure can be 30 mTorr to 2 Torr, preferably 100 to 500 mTorr. Then power supply 108 is turned on to provide plasma power to chamber 102 through electrodes 106. The power supply can be 10 to 2000 watts, preferably 150 to 500 watts. The frequency of power supply 108 can be from 0 (DC) to 10 GHz (microwave). The plasma gas is energized into a plasma that reacts with the surface of glass slides 104 and removes contaminants thereon. Power supply 108 is turned on for a period of 0.1 to 120 minutes, preferably 5 to 30 minutes. After the power supply is turned off, valve 132 is opened to allow the plasma gas to be removed from the chamber. When the pressure inside chamber 102 drops to the baseline pressure, valve 132 is closed.

The following describes a silanization process using the silanization system 100. After the glass slides are thoroughly cleaned by the plasma, oven 128 is adjusted to a temperature sufficient to vaporize the organosilane solution 118 in vessel 116, and the temperature in chamber 102 is adjusted to a level sufficient to facilitate silane coupling reaction. The temperature of the chamber may be controlled by the heat generated by heater 128, or by a separate heater (not shown). Solution 118 contains compounds suitable for use as silane coupling agents, such as amines, aldehydes, epoxy, isocyanide, thiols, hydroxyl, carboxyl, vinyl, or halocarbons (e.g., fluorocarbons). The oven temperature can be room temperature to 300° C., preferably room temperature to 150° C. In one example where aminosilane is used, the oven temperature is maintained at 80° to 90° C. In another example where epoxysilane is used, the oven temperature is adjusted to about 150° C. The chamber temperature can be room temperature to 300° C., preferably 50° to 120° C. Valve 120 is opened to allow the vapor from solution 118 to enter chamber 102 through inlet 114. When the chamber pressure reaches a preset pressure of 50 mTorr to 760 Torr, preferably 0.5 to 5 Torr, valve 120 is closed. After a preset time of 6 seconds to 20 hours, preferably 15 to 60 minutes, a layer of organosilane is deposited on the glass slides 104. Valve 132 is then open, and vacuum pump 112 removes gas from the chamber. Valve 132 is closed when the chamber pressure drops to the baseline pressure.

The following describes a curing process used after the glass slides have been silanized. The curing process can be conducted in vacuum or with ambient gas to distribute heat more evenly within the chamber. Any gas that does not react with the silane layer can be used to distribute heat. Preferably, N₂, Ar, or other inert gases may be used. As an example, mass flow controller 130 is adjusted to allow nitrogen gas to enter chamber 102 through inlet 110 until chamber pressure reaches a preset value of 0 to 760 Torr, preferably 10 to 50 Torr. Chamber 102 is maintained at a preset temperature of 50° to 500° C., preferably 100° to 200° C., in order to bake the glass slides 104. The baking process dries the slides and “cures” the slides by enhancing the uniformity of the organosilane layer over the slides. Baking also allows the organosilane layer to couple more securely to the slides. The baking process is performed for a period of 0.1 minutes to 20 hours, preferably 15 to 60 minutes. A longer baking period is needed when a lower temperature is used, and vice versa. Then valve 132 is opened, and vacuum pump 112 pumps the gases out of chamber 102. When the chamber pressure lowers to the baseline pressure, valve 132 is closed. A vent valve (not shown) of chamber 102 is opened to allow nitrogen or room air to enter the chamber. The silanized glass slides are then removed from chamber 102.

The silanized glass slides are “activated” in the sense that each contains an organosilane layer that includes silane molecules with functional groups that interacts, covalently or non-covalently, with target compounds. Examples of the functional groups are amine, aldehyde, epoxy, isocyanide, thiol, mercapto, hydroxyl, carboxyl, vinyl, disulfide, halogen-substituted alkyl, succinimide, acryl, methacryl, and halocarbon (e.g., fluorocarbon). Note that the functional groups of the organosilane layer may be of the same type (e.g., they are all amines), or they may be of different types (e.g. amines plus hydroxyls). A glass slide may contain an organosilane layer having one of the above functional group, or a mixture of the above functional groups. Examples of target compounds are organic molecules DNA, oligos, and proteins. The silanized glass slides can be sealed in packages for later use, or be further processed to produce DNA microarrays or other types of biochips.

An advantage of using silanization system 100 is that glass slides can be conveniently cleaned and silanized in a laboratory at a low cost. The glass slides can be silanized shortly before target compounds are attached to the slides, thereby ensuring the freshness of the silanized slides. In comparison, silanized glass slides purchased from outside vendors have much shorter lifetime since they have already been on the shelf for several days or months. Thus, microarrays or biochips produced from slides that are cleaned and silanized by silanization system 100 may have a longer lifetime in the laboratory.

Another advantage of using silanization system 100 is that a single chamber 102 can be used for the plasma cleaning, water deposition (described below), silanization, and curing of the glass slides 104. By eliminating the need for moving the glass slides from one chamber to another when performing different processing steps, the likelihood that the slides will come into contact with dust or other contaminants is reduced. This ensures the quality of the silanized glass slides.

Treatment of the glass slides 104 may also include deposition of water or hydrogen peroxide before, during, or after organosilane compounds are deposited on the glass slides 104. A vessel 122 containing water 124 (or hydrogen peroxide) is coupled to inlet 114 through valve 126. The steps for cleaning the glass slides using a plasma is the same as described previously. When the plasma gas is pumped out of chamber 102, valve 132 is closed, and then valve 126 is opened so that water vapor enters chamber 102 through inlet 114. The temperature of chamber 102 is maintained at a preset value between room temperature to 300° C., preferably room temperature to 100° C. As water vapor enters chamber 102, the chamber pressure increases. When the pressure increases to a preset value between 50 mTorr to 760 Torr, preferably 0.5 Torr to 5 Torr, valve 126 is closed. Water acts as a catalyst to promote polymerization of organosilanes and allows the organosilane compounds to have a better coupling reaction with the glass slides. After 30 to 60 minutes, valve 132 is opened and vacuum pump 112 pumps the water vapor out of chamber 102. When the chamber pressure is reduced to the baseline pressure, valve 132 is closed. Afterwards, vapor deposition of organosilane compound (or compounds) and baking (or curing) of the silnanized glass slides are conducted in the same manner as described previously.

Additional vessels (not shown) may be used to contain different types of organosilane solutions. More than one type of organosilanes may be introduced into chamber 102 at the same time. Different types (or different combinations) of organosilanes may also be introduced into chamber 102 sequentially, one after another.

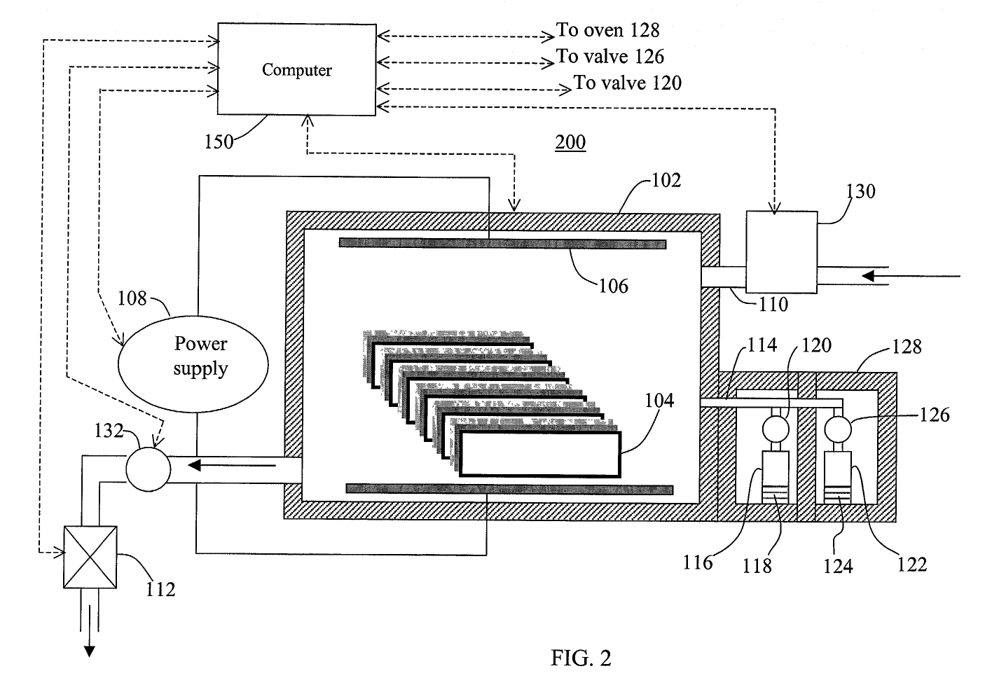

An advantage of silanization system 100 is that the cleaning, water deposition, silanization, and curing steps are performed in the same chamber, so the whole process can be easily automated. Referring to FIG. 2, a computer 150 is programmed to control power supply 108, valves 120, 132, 126 (described below), mass flow controller 130, and oven 128 to regulate the plasma cleaning, water deposition, silanization, and curing processes automatically. Different protocols setting forth the process conditions (e.g., chamber temperature, chamber pressure, time duration of the process) can be predefined and stored in a disk drive (not shown) of computer 150. When more than one type of organosilane solution is used, the protocols may define which organosilane solution (or which combination of organosilane solutions) is used to silanized the substrate surface, and the sequence in which individual or combination of organosilane solutions are applied. The protocol may also define whether to use water deposition, either before, during, or after, the silanization process. Different protocols may be defined for substrates that are composed of different materials. Different protocols may be defined for substrates intended for different purposes. These protocols may be later recalled from the disk drive in response to a user selection. Computer 150 then controls the processes automatically according to the predefined protocols.

Referring to FIG. 3, another example of a silanization system 300 has an external inductive electrode 136 that is connected to plasma power supply 108 and produces up-stream plasma in chamber 136. The plasma in chamber 136 then diffuses into chamber 102 and clean the glass slides 104. Other means of coupling plasma energy into chamber 102 to energize the gases to produce a plasma for slide treatment may also be used. A support 138 holds slides 104 in chamber 102.

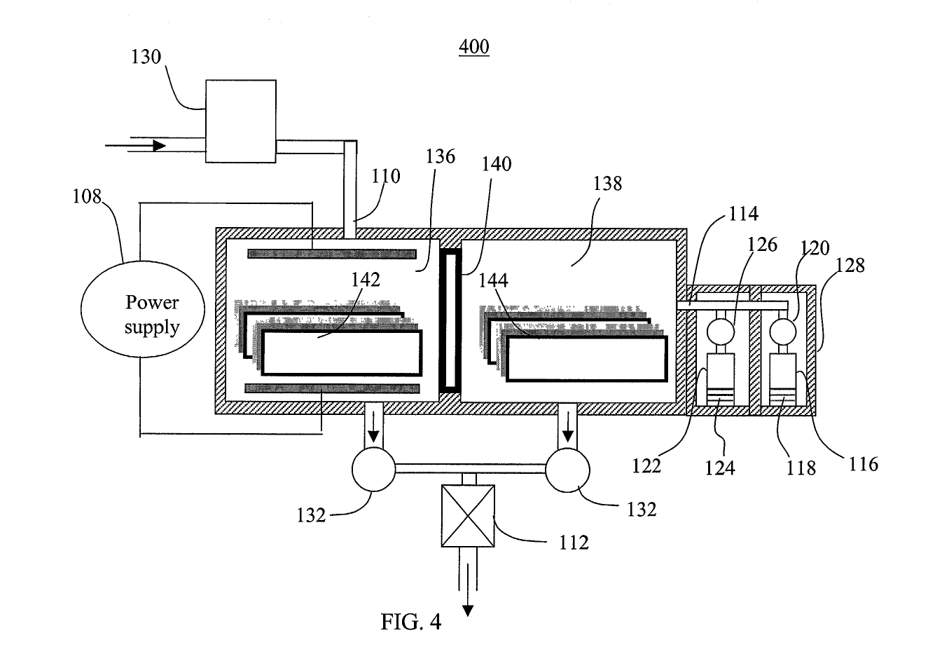

Referring to FIG. 4, another example of a silanization system 400 has a first chamber 136 and a second chamber 138. First chamber 136 is used to clean a set of substrates 142 using a plasma. Second chamber 138 is used to silanized and cure the set of substrates. Gas enters first chamber 136 through inlet 110 and is energized by power provided by power supply 108 into a plasma. The plasma cleans the surface of substrates 142. Gas containing an organosilane compound is generated from solution 118 and enters second chamber 138 through inlet 114. Water vapor is generated from water 124 and enters second chamber 138 through inlet 114. Valves 120 and 126 regulate the flow of gas containing the organosilane compound and water vapor, respectively, into second chamber 138.

First chamber 136 and second chamber 138 are separated by a gate 140 that can move between an open position and a closed position. When gate 140 is moved to the closed position, first chamber 136 is sealed off from second chamber 138 so that different processes can operate in the chambers at the same time. A set of substrates 142 may be plasma cleaned in first chamber 136 while another set of substrates 144 are silanized in second chamber 138. When gate 140 is moved to the open position, first chamber 136 is connected to second chamber 138, and substrates can be moved from the first chamber to the second chamber. A robotic arm (not shown) may be used to move the substrates from the first chamber to the second chamber.

An advantage of using silanization system 400 is that much time is saved by plasma cleaning and silanizing different sets of substrates simultaneously. In addition, although first and second chambers are connected when gate 140 is moved to the open position, first and second chambers are sealed off from the room environment so that the substrates will not be contaminated by room air before the substrates are properly silanized.

Table 1 shows water contact angles measured from of a set of twelve glass slides (or silicon wafers) treated under various conditions. Each value shown in the table is obtained from measurements of 3 slides (or wafers) with 5 measurements per slide (or wafer). The first set of measurements were made on glass slides cleaned by O₂ plasma at 70° C. for 20 minutes. The O₂ pressure during plasma cleaning was 200 mTorr, and the power was 250 watts. The water contact angles measured from the glass slides were 6.4±0.8 degrees before plasma cleaning, and were 4.5±0.1 degrees after cleaning. After plasma cleaning, water vapor deposition was conducted at 1 Torr for 30 minutes. Then vapor deposition of 3-aminopropyltrimethoxysilane (hereafter abbreviated as 3-APTMS) was conducted at 2 Torr for 60 minutes. The water contact angles of the glass slides were 52.5±2.2 degrees after the vapor deposition.

TABLE 1

| | | Water | | Water | | |
|---|---|---|---|---|---|---|
| | | contact | | contact | | Water |
| | | angle | | angle | | contact |
| | | (degree of) | | (degree of) | | angle |
| | | glass side | | glass side | | (degree) of |
| | | before | | after | Vapor | glass side |
| | Type of | plasma | Type of | plasma | deposition | after vapor |
| | substrate | cleaning | plasma | cleaning | compound(s) | deposition |
| Measure- | Glass | 6.4 ± 0.8 | O₂ plasma | 4.5 ± 0.1 | H₂O and 3- | 52.5 ± 2.2 |
| ment 1 | slide | | | | APTMS | |
| Measure- | Glass | 6.0 ± 0.9 | H₂O | 4.0 ± 0.3 | H₂O and 3- | 42.8 ± 4.0 |
| ment 2 | slide | | plasma | | APTMS | |
| Measure- | Glass | 6.3 ± 0.4 | Air plasma | 4.8 ± 0.6 | H₂O and 3- | 51.6 ± 1.7 |
| ment 3 | slide | | | | APTMS | |
| Measure- | Glass | 5.5 ± 0.7 | H₂O | 4.1 ± 0.5 | 3-APTMS | 52.5 ± 2.2 |
| ment 4 | slide | | plasma | | | |
| Measure- | Glass | 6.6 ± 0.6 | O₂ plasma | 5.6 ± 0.8 | H₂O and | 54.2 ± 1.5 |
| ment 5 | slide | | | | GPTMS | |
| Measure- | Glass | | H₂O | 4.4 ± 0.7 | H₂O and | 54.4 ± 0.9 |
| ment 6 | slide | | plasma | | GPTMS | |
| Measure- | Glass | | Air plasma | 5.7 ± 0.7 | H₂O and | 56.3 ± 1.9 |
| ment 7 | slide | | | | GPTMS | |
| Measure- | Silicon | 68.8 ± 1.5 | O₂ plasma | Less than 4 | H₂O and 3- | 57.6 ± 0.1 |
| ment 8 | wafer | | | degrees | APTMS | |
| Measure- | Silicon | | H₂O | Less than 4 | H₂O and 3- | 58.6 ± 0.1 |
| ment 9 | wafer | | plasma | degrees | APTMS | |

The second set of measurements were made on glass slides cleaned by H₂O plasma at 70° C. for 20 minutes. The H₂O vapor pressure during plasma cleaning was 200 mTorr, and the plasma power was 250 watts. The water contact angles measured from the glass slides were 6.0±0.9 degrees before plasma cleaning, and were 4.0±0.3 degrees after cleaning. After plasma cleaning, water vapor deposition was conducted at 1 Torr for 30 minutes. Then vapor deposition of 3-APTMS was conducted at 2 Torr for 60 minutes. The water contact angles of the glass slides were 42.8±4.0 degrees after vapor deposition.

The third set of measurements were made on glass slides cleaned by plasma generated from room air at 70° C. for 20 minutes. The air pressure during plasma cleaning was 200 mTorr, and the plasma power was 250 watts. The water contact angles measured from the glass slides were 6.3±0.4 degrees before plasma cleaning, and were 4.8±0.6 degrees after cleaning. After plasma cleaning, water vapor deposition was conducted at 1 Torr for 30 minutes. Then vapor deposition of 3-APTMS was conducted at 2 Torr for 60 minutes. The water contact angles of the glass slides were 51.6±1.7 degrees after vapor deposition.

The fourth set of measurements were made on glass slides cleaned by O₂ plasma at 70° C. for about 20 minutes. The air pressure during plasma cleaning was 200 mTorr, and the plasma power was 250 watts. The water contact angles measured from the glass slides were 5.5±0.7 degrees before plasma cleaning, and were 4.1±0.5 degrees after cleaning. For this measurement, water vapor deposition was not used. After plasma cleaning, the vapor deposition of 3-APTMS was conducted at 2 Torr for about 60 minutes. The water contact angles of the glass slides were 52.5±2.2 degrees after vapor deposition.

The fifth set of measurements were made on glass slides cleaned by O₂ plasma at 70° C. for 20 minutes. The air pressure during plasma cleaning was 200 mTorr, and the plasma power was 250 watts. The water contact angles measured from the glass slides were 6.6±0.6 degrees before plasma cleaning, and were 5.6±0.8 degrees after cleaning. After plasma cleaning, water vapor deposition was conducted at 1 Torr for 30 minutes. Then vapor deposition of glycidoxypropyltrimethoxysilane (abbreviated as GPTMS) was conducted at 450 mTorr for 60 minutes. The water contact angles of the glass slides were 54.2±1.5 degrees after vapor deposition.

The sixth set of measurements were made on glass slides cleaned by H₂O plasma at 70° C. for 20 minutes under air pressure of 200 mTorr with 250 Watts of plasma power. The water contact angles measured from the glass slides were 4.4±0.7 degrees after cleaning. After plasma cleaning, water vapor deposition was conducted at 1 Torr for 30 minutes. Then vapor deposition of GPTMS was conducted at 450 mTorr for 60 minutes. The water contact angles of the glass slides were 54.4±0.9 degrees after vapor deposition.

The seventh set of measurements were made on glass slides cleaned by air plasma at 70° C. for 20 minutes under air pressure of 200 mTorr with 250 Watts of plasma power. The water contact angles measured from the glass slides were 5.7±0.7 degrees after cleaning. After plasma cleaning, water vapor deposition was conducted at 1 Torr for 30 minutes. Then vapor deposition of GPTMS was conducted at 450 mTorr for 60 minutes. The water contact angles of the glass slides were 56.3±1.9 degrees after vapor deposition.

The eighth set of measurements were made on silicon wafers cleaned by O₂ plasma at 70° C. for 20 minutes under air pressure of 200 mTorr with 250 Watts of plasma power. The water contact angles after cleaning were less than 4 degrees. After plasma cleaning, water vapor deposition was conducted at 1 Torr for 30 minutes. Then vapor deposition of 3-APTMS was conducted at 450 mTorr for 60 minutes. The water contact angles of the silicon wafers were 57.6±0.1 degrees after vapor deposition.

The ninth set of measurements were made on silicon wafers cleaned by H₂O plasma at 70° C. for 20 minutes under air pressure of 200 mTorr with 250 Watts of plasma power. The water contact angles measured from the silicon wafers were less than 4 degrees after cleaning. After plasma cleaning, water vapor deposition was conducted at 1 Torr for 30 minutes. Then vapor deposition of GPTMS was conducted at 450 mTorr for 60 minutes. The water contact angles of the silicon wafers were 58.6±0.1 degrees after vapor deposition.

A number of embodiments of the invention have been described. Nevertheless, it will be understood that various modifications may be made without departing from the spirit and scope of the invention. For example, the chamber 102 can be cube or cylindrically shaped, and can have varying sizes. The electrodes 106 may be square or round shaped, internal or external to chamber 102, and either inductive or capacitive in the coupling of plasma energy to the chamber. Devices other than an oven may be used to heat the organosilane solutions and water. For example, a heating coil or heating pad may be used. Vessels 116 and 122 are shown coupled to the chamber through inlet 114. They may also be coupled to the chamber through separate inlets. Likewise, additional vessels containing organosilane solutions may be coupled to the chamber through inlet 114 or other inlets. For system 400, various means can be used to move the substrates from the first chamber to the second chamber. For example, a rotatable plate may be used to rotate the substrates from the first chamber to the second chamber. A slidable plate may also be used to slide the substrates from one chamber to another chamber.

Different types of silanes additional to the ones mentioned may be used to silanize the cleaned glass slides. Substrates may be composed of materials other than glass, such as quartz, ceramic, silicon, metal, or polymer, and may include additional materials. Substrates may be of various shapes and may have various layers as long as it has a surface that allows silane coupling reaction to occur. The substrate may be part of a larger device. The temperature and pressure conditions may be different from the ones described may be used as long as plasma cleaning and silanization can occur. The silanizing step may be performed with or without cleaning the chamber. In the steps where water deposition is used, hydrogen peroxide deposition may also be used.

Accordingly, other embodiments are within the scope of the following claims.

What is claimed is:

1. A method comprising:
providing a chamber having a substrate therein;
cleaning a surface of the substrate in the chamber with a plasma; and
silanizing the cleaned surface in the chamber to produce a layer of covalently bonded silane molecules having functional groups.

2. The method of claim 1, wherein each of the functional groups is amine, aldehyde, epoxy, isocyanide, thiol, mercapto, hydroxyl, carboxyl, vinyl, halocarbon, disulfide, halogen-substituted alkyl, succinimide, methacryl, or acryl.

3. The method of claim 1, wherein the plasma is O₂ plasma, air plasma, CO₂ plasma, Ar plasma, N₂ plasma, hydrogen plasma, helium plasma, water plasma, hydrogen peroxide plasma, or a combination thereof.

4. The method of claim 1, further comprising baking the silanized substrate in the chamber.

5. The method of claim 1, wherein the silanizing step is performed without cleaning the chamber.

6. The method of claim 5, further comprising depositing water or hydrogen peroxide on the surface of the substrate.

7. The method of claim 1, further comprising depositing water or hydrogen peroxide on the surface of the substrate.

8. The method of claim 7, wherein the water or hydrogen peroxide depositing step is performed before the silanizing step.

9. The method of claim 7 in which the water or hydrogen peroxide depositing step is performed after the silanizing step.

10. The method of claim 1 wherein the substrate comprises glass, quartz, ceramic, silicon, metal, gallium arsenide, or polymer.

11. A method comprising:
providing a substrate in a chamber;
providing water vapor in the chamber; and
generating a plasma from the water vapor to clean a surface of the substrate.

12. The method of claim 11, further comprising silanizing the cleaned surface to produce a silane layer having covalently bonded silane molecules.

13. The method of claim 11 wherein the plasma generating step is performed at 20 to 300° C.

14. The method of claim 13 wherein the plasma generating step is performed at 20 to 100° C.

15. The method of claim 14 wherein the plasma generating step is performed at a chamber pressure of 50 to 1000 mTorr.

16. The method of claim 13 wherein the plasma generating step is performed at a chamber pressure of 50 to 1000 mTorr.

17. The method of claim 12 wherein the plasma generating step is performed at a chamber pressure of 50 to 1000 mTorr.

18. A method comprising:
providing a substrate in a chamber;
providing hydrogen peroxide vapor in the chamber;
generating a plasma from the hydrogen peroxide vapor to clean a surface of the substrate; and
providing an organosilane gas in the chamber to silanize the cleaned surface.

19. A method comprising:
providing a chamber having a substrate therein;
generating a plasma in the chamber; and
introducing a first gas having first organosilane molecules into the chamber.

20. The method of claim 19, further comprising introducing a second gas having second organosilane molecules into the chamber after the step of introducing the first gas.

21. The method of claim 19, farther comprising introducing water vapor or hydrogen peroxide vapor into the chamber after the step of generating the plasma.

22. The method of claim 19, further comprising introducing water vapor or hydrogen peroxide vapor into the chamber after introducing the first gas into the chamber.

23. The method of claim 19, further comprising introducing water vapor or hydrogen peroxide vapor into the chamber before introducing the first gas into the chamber.

24. An apparatus comprising:
a chamber;
electrodes to supply power to the chamber for generating a plasma;
an inlet to allow a gas suitable for generating a plasma to enter the chamber; and
a vessel coupled to the chamber, the vessel containing an organosilane solution.

25. The apparatus of claim 24 in which the organosilane solution includes a compound suitable for silanizing a surface of a substrate.

26. The apparatus of claim 24, further comprising a power supply coupled to the electrodes to supply power to the chamber, the power suitable for generating a plasma in the chamber.

27. The apparatus of claim 24, further comprising a heater to heat the solution.

28. The apparatus of claim 27, further comprising a second vessel also coupled to the chamber, the second vessel containing water or hydrogen peroxide.

29. The apparatus of claim 24, further comprising a second vessel also coupled to the chamber, the second vessel containing water or hydrogen peroxide.

30. An apparatus comprising:
a chamber for receiving a substrate therein;
means for plasma cleaning a surface of the substrate in the chamber; and
means for silanizing the cleaned surface in the chamber.

31. The apparatus of claim 30, further comprising means for depositing water or hydrogen peroxide on the surface of the substrate.

32. The apparatus of claim 31 in which the silanizing means includes a first vessel for storing a first organosilane solution.

33. The apparatus of claim 32 in which the silanizing means includes a second vessel suitable for storing a second organosilane solution that is different from the first organosilane solution.

34. The apparatus of claim 30 in which the silanizing means includes a first vessel suitable for storing a first organosilane solution.

35. The apparatus of claim 34 in which the silanizing means includes a second vessel suitable for storing a second organosilane solution different from the first organosilane solution.

36. The apparatus of claim 34 in which the silanizing means includes additional vessels suitable for storing organosilane solutions, the first vessel and the additional vessels each storing a different organosilane solution.

37. The apparatus of claim 36, further comprising a computer to select organosilane solutions for silanizing the cleaned surface according to a predefined protocol.

38. The apparatus of claim 37 in which the predefined protocol defines the sequence or combination of the selected organosilane solutions for silanizing the cleaned surface.

39. An apparatus comprising:
a first chamber;
a second chamber;
a gate disposed between the first and the second chambers, the gate movable between a first position where the first chamber is connected to the second chamber and a second position where the first chamber is closed off from the second chamber;
electrodes to supply power to the first chamber, the power suitable for generating a plasma in the first chamber;
an inlet to allow a gas to enter the first chamber, the first gas suitable for generating the plasma; and
a vessel coupled to the second chamber, the vessel configured to contain an organosilane solution.

40. The apparatus of claim 39, further comprising a heater to heat the organosilane solution.

41. The apparatus of claim 40, further comprising a second vessel also coupled to the second chamber, the second vessel containing water or hydrogen peroxide.

42. The apparatus of claim 41, further comprising means for moving a substrate from the first chamber to the second chamber when the gate is moved to the first position.

43. The apparatus of claim 39, further comprising a second vessel also coupled to the second chamber, the second vessel containing water or hydrogen peroxide.

44. The apparatus of claim 43, further comprising means for moving a substrate from the first chamber to the second chamber when the gate is moved to the first position.

45. The apparatus of claim 39, further comprising additional vessels also coupled to the second chamber, the additional vessels containing organosilane solutions, the first vessel and the additional vessels storing different organosilane solutions.

46. The apparatus of claim 43, further comprising a computer to select one or a combination of organosilane solutions for silanizing the surface, the selection of one or a combination of solutions performed according to a predefined protocol.

47. The apparatus of claim 46 in which the predefined protocol also defines the sequence of the selected one or combination of organosilane solutions.

48. An apparatus comprising:
a chamber;
electrodes to supply power to the chamber for generating a plasma;
a first inlet coupled to the chamber to allow a first gas suitable for generating a plasma to enter the chamber;
a second inlet coupled to the chamber to allow a second gas to enter the chamber, the second gas including an organosilane compound; and
an outlet coupled to the chamber to allow the first and second gases to exit the chamber.

49. The apparatus of claim 48, further comprising a heater configured to receive a vessel that contains an organosilane solution that generates the second gas when the solution is heated by the heater.

50. The apparatus of claim 49, further comprising a power supply coupled to the electrodes to supply power for generating the plasma.

51. The apparatus of claim 50, further comprising a mass flow controller coupled to the first inlet to regulate the first gas flowing through the first inlet.

52. The apparatus of claim 51, further comprising a computer configured to control the power supply, the mass flow controller, and the heater.
